(19) United States
(12) Patent Application Publication
(10) Pub. No.: US 2008/0285221 A1
(43) Pub. Date: Nov. 20, 2008

(54) Portable Computer with Space Efficient Cubic Configuration

(76) Inventors: Bruce Imsand, Madison, AL (US); Greg O'Bryant, Madison, AL (US)

Correspondence Address: BRADLEY ARANT ROSE & WHITE LLP, 200 CLINTON AVE. WEST, SUITE 900, HUNTSVILLE, AL, 35801, US

(21) Appl. No.: 12/061,538

(22) Filed: Apr. 2, 2008

Related U.S. Application Data
(60) Provisional application No. 60/909,710, filed on Apr. 2, 2007.

(51) Int. Cl. H05K 7/00; H05K 7/20

(52) U.S. Cl. 361/681; 361/687; 361/685

(57) ABSTRACT

A space efficient, portable computer unit has been developed. The computer unit includes a unit case that is generally cubic shaped and a cooling system. The cooling system includes multiple exhaust fan mounted on the rear of the unit case and a filter mounted on the front of the unit case. The exhaust fan draws cooling air from the exterior of the unit case through the filter. The internal computer components are mounted inside the unit case, so that each internal computer component is arranged to receive cooling air directly from the filter and avoid heat stacking of the components.

### CROSS-REFERENCE TO RELATED APPLICATIONS

This application claims priority from U.S. Provisional Patent Application No. 60/909,710 titled “Portable Computer with Space Efficient Cubic Configuration” that was filed on Apr. 2, 2007.

### FIELD OF THE INVENTION

The invention relates generally to portable computers. More specifically, the present invention relates to a portable computer with a space efficient cubic configuration.

### BACKGROUND ART

Portability is a feature that is greatly desired in computers. A whole sub-class of computers commonly called “notebooks” or “laptops” has developed around the concept of portability. However, when compared with a more conventional desktop or “workstation” computer, the performance of notebooks is generally lacking. Specifically, notebook computers lag behind workstation in capabilities such as processor type and speed, available memory, etc. due to constraints on space and power consumption. There is a need for portable or easily transported servers and workstations which combine extremely large storage and performance with high reliability power supply systems that can be moved to a remote location, run off any available power and provide centralized storage and centralized compute resources. Like to notebook computer, such as server should be able to run off internal batteries if reliable power is not available and it should be able to run off external power available to fulfill the demand of highly reliable portable server and workstation computing equipment.

A potential solution is the development and use of more robust “portable computers” that have the performance characteristics of workstations and servers combined with the portability desired by users. While portable computers are typically smaller in size than workstations, there exists a significant need for the most space efficient and lightest weight configuration without compromising performance.

### SUMMARY OF THE INVENTION

In some aspects, the invention relates to a space efficient, portable computer unit, comprising a unit case that is generally cubic shaped; a cooling system comprising, at lease one exhaust fan mounted on the rear of the unit case, and a filter mounted on the front of the unit case, where the exhaust fan draws cooling air from the exterior of the unit case through the filter, and a plurality of internal computer components mounted inside the unit case, where each internal computer component is arranged to receive cooling air directly from the filter.

In other aspects, the invention relates to a space efficient, portable computer unit, comprising: an aluminum unit case that is generally cubic shaped, where the unit case is about 12.75 inches wide, 11 inches high, and 12.75 inches deep; a folding flat panel display screen mounted on front of the unit case; four cushion knobs mounted on the top of the unit case, where the cushion knobs are arranged to provide a seating surface for a second portable computer unit to be stacked on the top of the unit case; two carry straps mounted on the top of the unit case; a cooling system comprising, a series of exhaust fans mounted on the rear of the unit case, and a filter mounted directly behind an air intake panel on the front of the unit case, where the exhaust fan draws cooling air from the exterior of the unit case through the air intake panel and the filter; and a plurality of internal computer components mounted inside the unit case, where each internal computer component is arranged to receive cooling air directly from the filter.

Other aspects and advantages of the invention will be apparent from the following description and the appended claims. dr

### BRIEF DESCRIPTION OF DRAWINGS

It should be noted that identical features in different drawings are shown with the same reference numeral.

FIGS. 1-7 show perspective views of a portable computer in a cubic configuration in accordance with various embodiments of the present invention.

FIG. 8 shows an exploded view of a removable hard drive magazine in accordance with one embodiment of the present invention.

FIGS. 9-11 show perspective views of a portable computer in a cubic configuration in accordance with various embodiments of the present invention.

FIGS. 12-19 show various views of the removable internal computer chassis of a portable computer in a cubic configuration in accordance with various embodiments of the present invention.

FIGS. 20 and 21 show perspective views of a 3×3 array of portable cubic computer units in accordance with various embodiments of the present invention.

### DETAILED DESCRIPTION

A portable computer in a space efficient cubic configuration is disclosed. The computer unit (hereafter “unit”) is designed to provide a powerful computer in a compact, portable configuration that measures 12.75″ W×11″ H×12.75″ D. In one embodiment, a single unit includes: eight (8) 64 bit CPUs; 8TB of removable hard disk storage; 24GB of main memory; and a 50GB Blu Ray optical drive. However, it should be understood that these components are examples only and a wide variety of components may be substituted by those skilled in the art. Other advantages of the unit include the ability to operate in high heat in excess of 50° C. Because the arrangement of components inside the unit all have fair access to fresh air and each subsystem expels exhaust to the rear, there is no heat stacking. In other words no component substantially preheats the air for another component. This allows the operational ambient temperatures to be higher without exceeding the rated specifications of hard drives and other critical components. Because all air flow is front to back, even a crowded stacked array of units can operate over the same temperature range.

It is noted that several features of the present invention reference inventions disclosed in U.S. patent application Ser. No. 11/620,772 titled “Uninterruptable Power Supply” and U.S. patent application Ser. No. 11/409,296 titled “Removable Hard Drive Module for a Computer”. Each of these applications are herein incorporated by reference in their entirety.

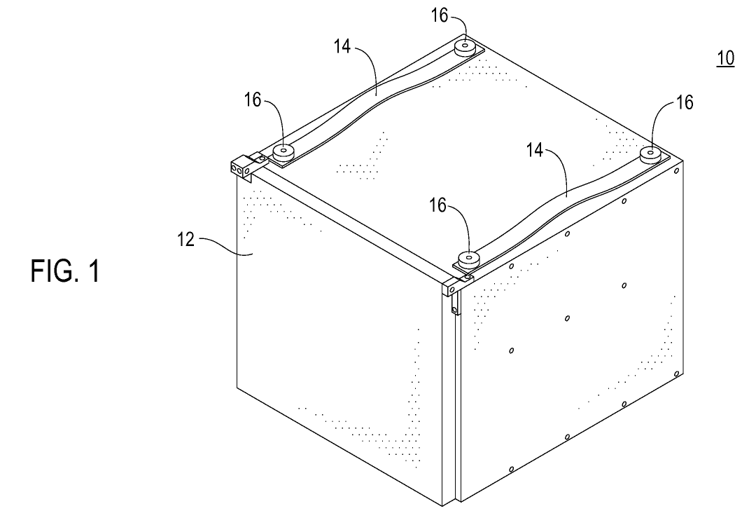

FIG. 1 shows an example of a portable computer unit 10 in a closed configuration. The unit 10 includes an optional flat panel display screen 12 that is folded down. Also shown, are two straps 14 that are used for hand carrying the unit 10. Each strap 14 is attached to the top of the unit 10 with two cushion knobs 16. The unit 10 may be made of lightweight materials such as machined aluminum or magnesium. In some embodiments, the unit weighs approximately 45 pounds. The cushion knobs 14 also provide a seating and cushioning surface for additional computer units to be placed on top of this unit when assembly an array of computers.

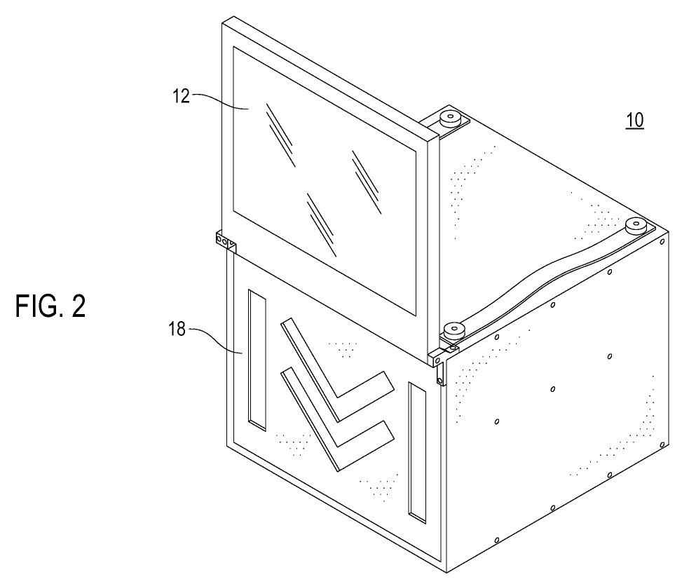

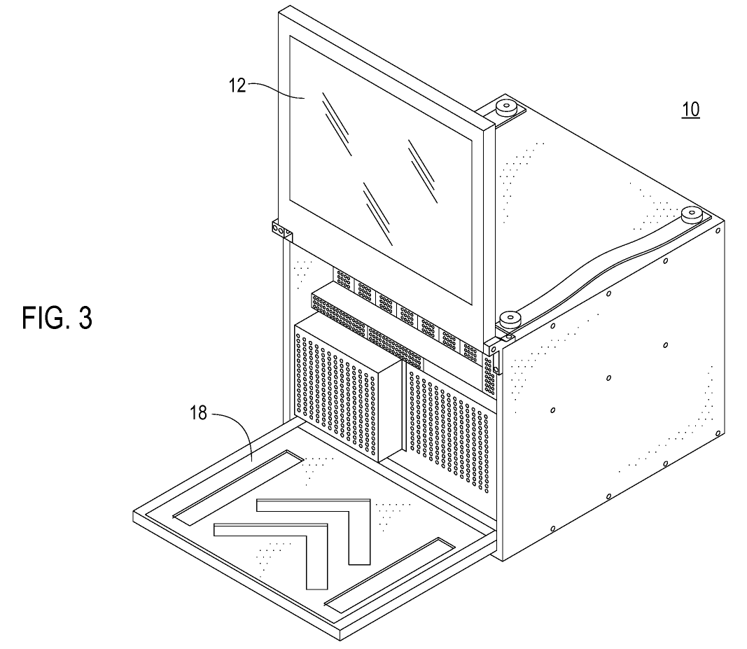

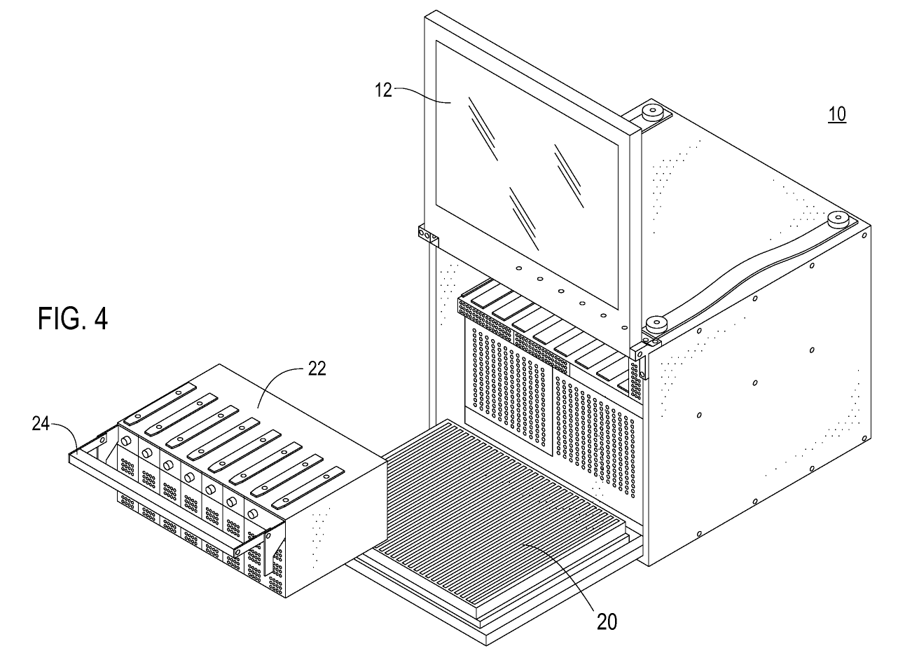

FIG. 2 shows the unit 10 in an open configuration with the display 12 folded up and exposing the air intake panel 18. All cooling air enters the unit 10 from this panel 18 and moves from the front to the rear of the unit. FIG. 3 shows the unit 10 with the air intake panel 18 folded down to reveal the internal components. FIG. 4 shows the air filter 20 that is attached to the air intake panel 18. The air filter 20 ensures that the air that reaches the internal components in clear by filtering out dirt, dust, etc. before it enters the unit 10.

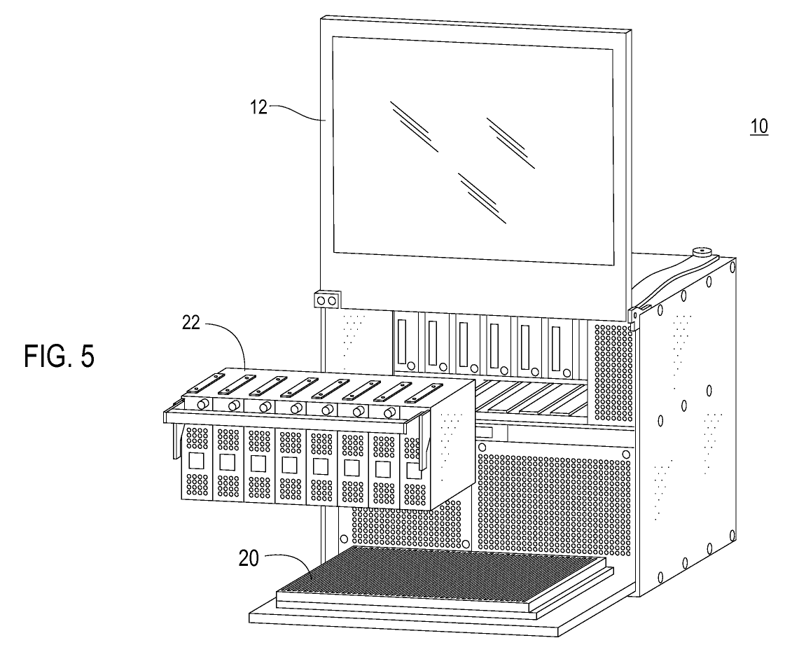

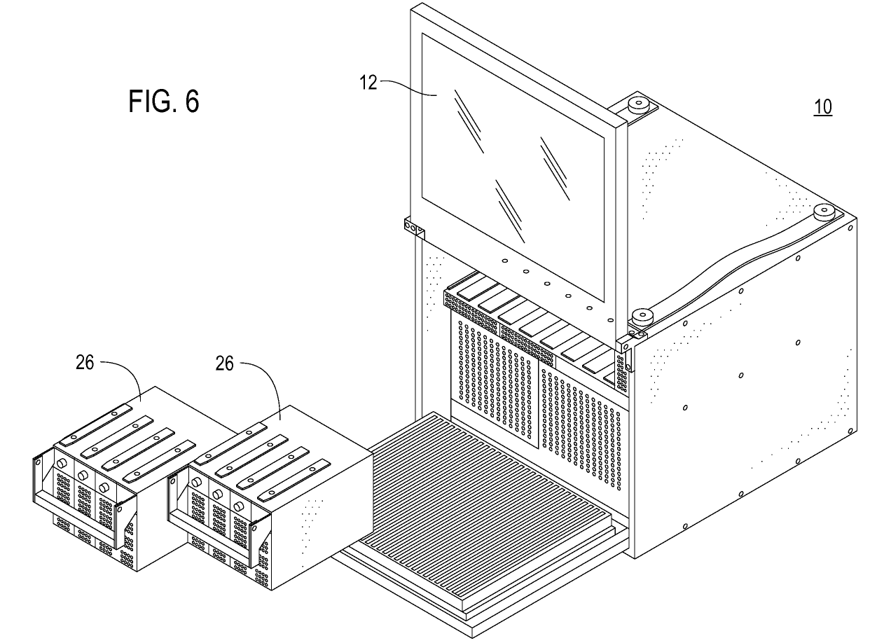

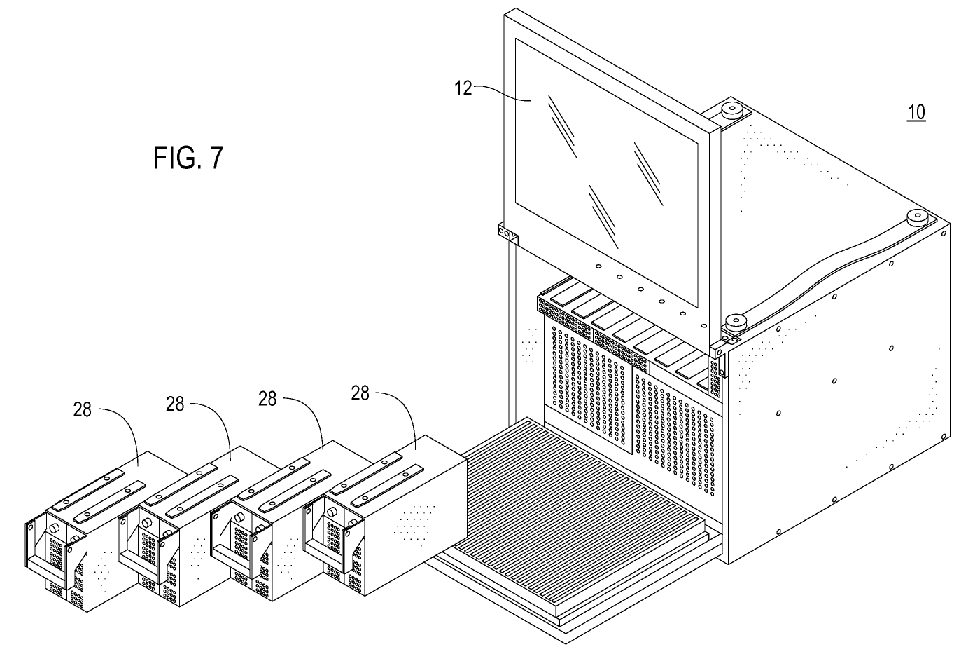

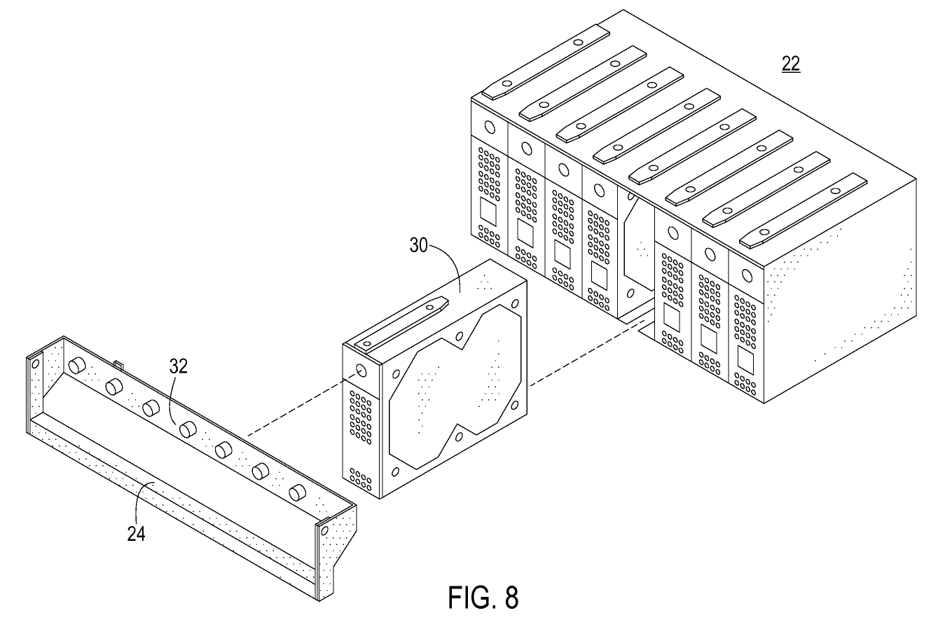

FIG. 4 also shows a single eight disc array hard drive magazine 22 that is removed from the unit 10. The magazine 22 includes handle 24 that allows the magazine 22 to be locked into place inside the unit 10. The handle swings up to unlock the magazine 22 and allow it to be removed from the unit 10. While an eight disc drive magazine is shown in FIGS. 4 and 5, other configurations of drive magazines could be used such as two separate four disc array hard drive magazines 26 (shown in FIG. 6) and four separate two disc array hard drive magazines 28 (shown in FIG. 7). FIG. 8 shows a more detailed exploded view of the eight disc drive magazine 22. The handle 24 is shown in the down or “locked” position. The handle 24 is attached to the magazine 22 with a bracket plate 32 that attaches across the front of the magazine 22 with a series of knurl screws that may be tightened or loosened by hand. Once the handle 24 is removed, individual disc drives 30 may be removed from the magazine 22.

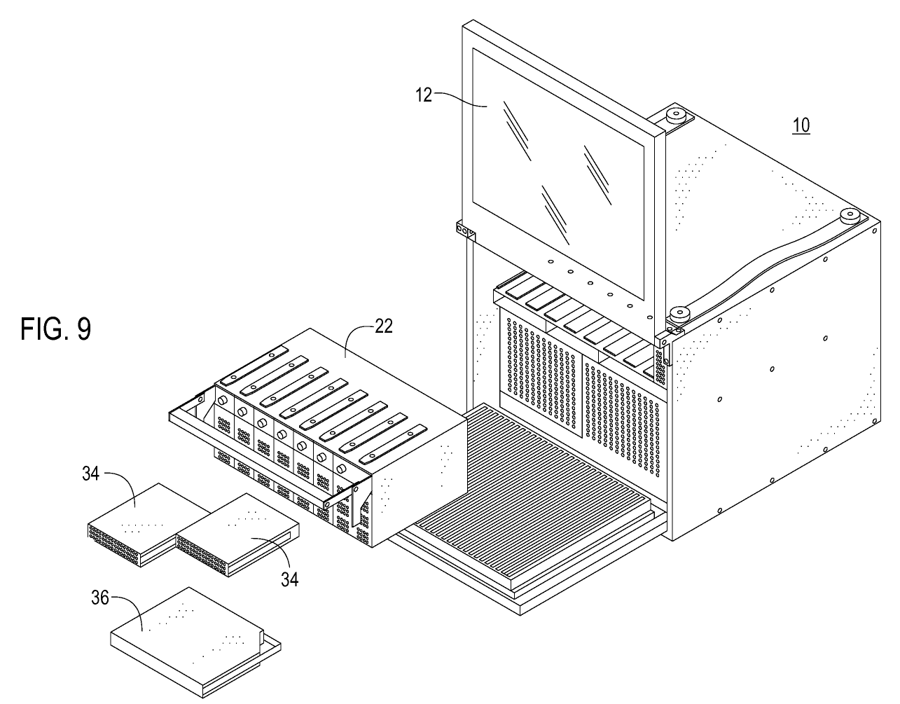

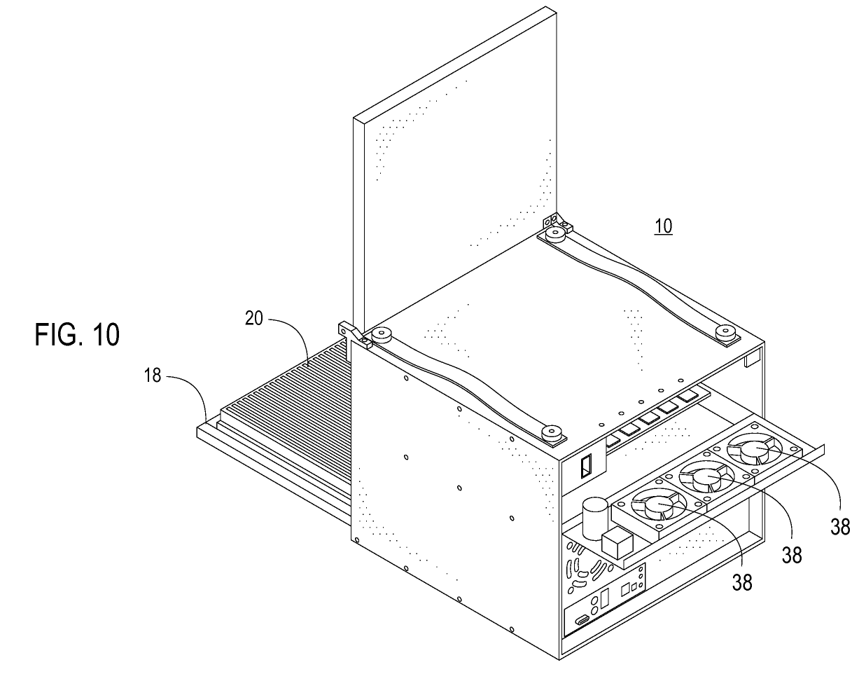

FIG. 9 shows another view of a unit 10 with additional components that are removable. The components include: a pair of system drives 34; and an optical drive 36. FIG. 10 shows a rear view of a unit 10 with an open access panel to show exhaust fans 38 for the unit 10. The open panel also allows for cables to be attached to peripheral devices. The fans 38 draw cooling air through the inlet panel 18 and filter 20 across the internal components and out the rear of the unit 10. The path of the air flow is a direct line across the internal components. This promotes maximum efficient of the cooling system.

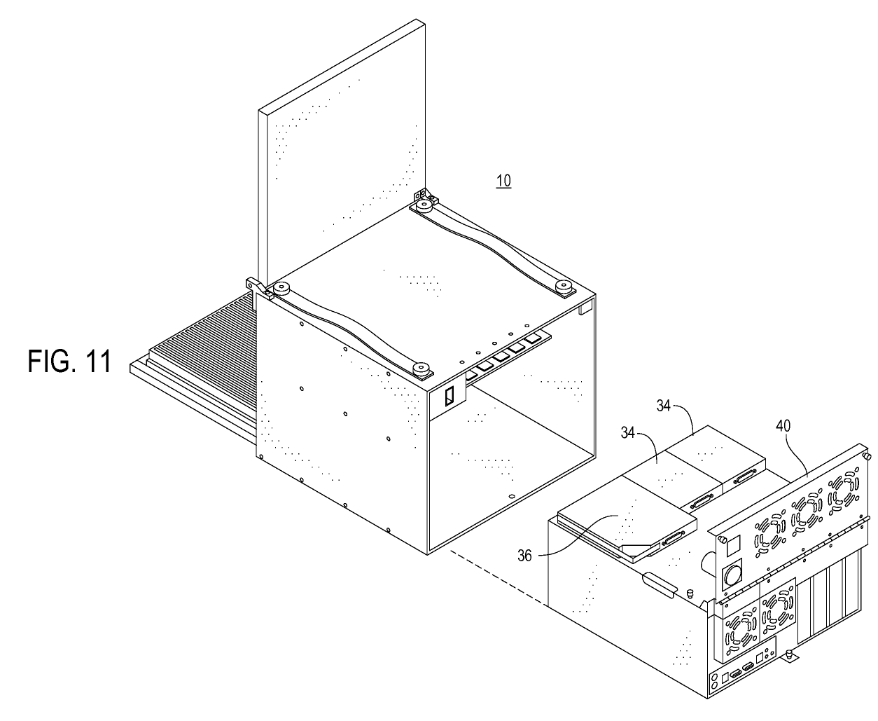

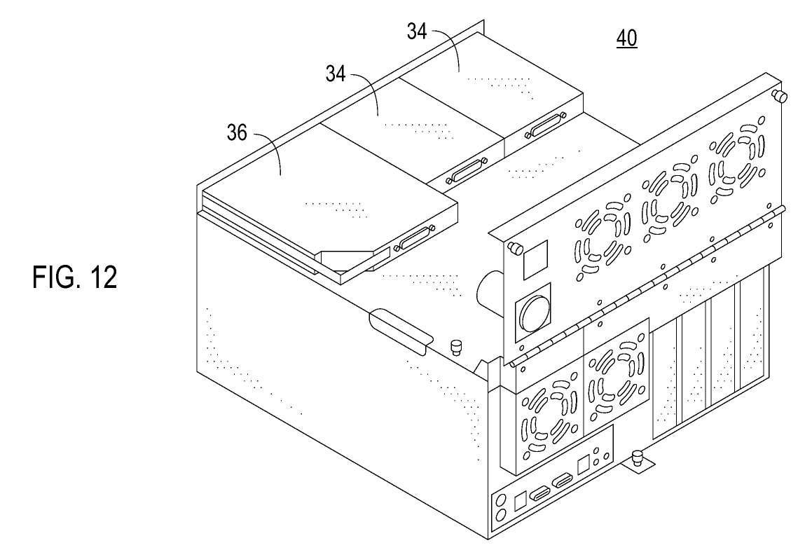

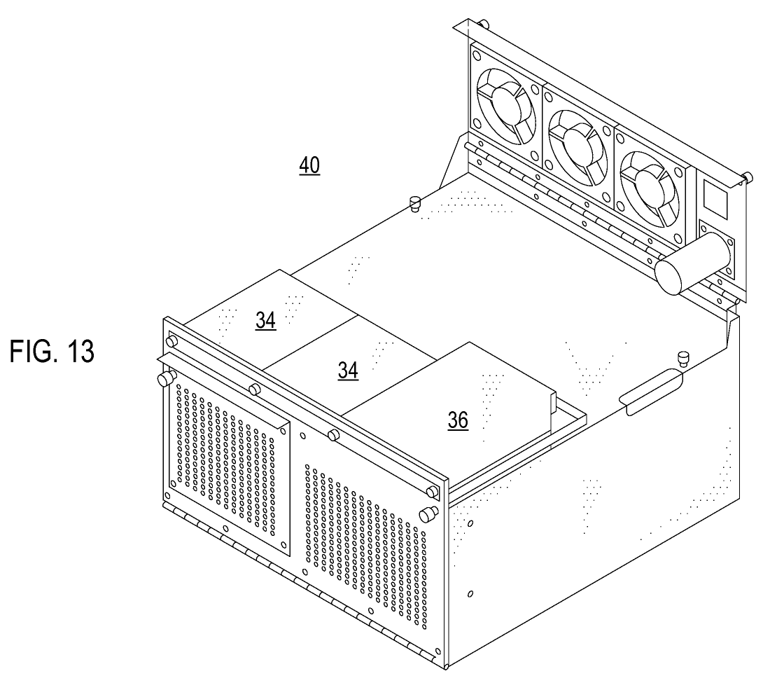

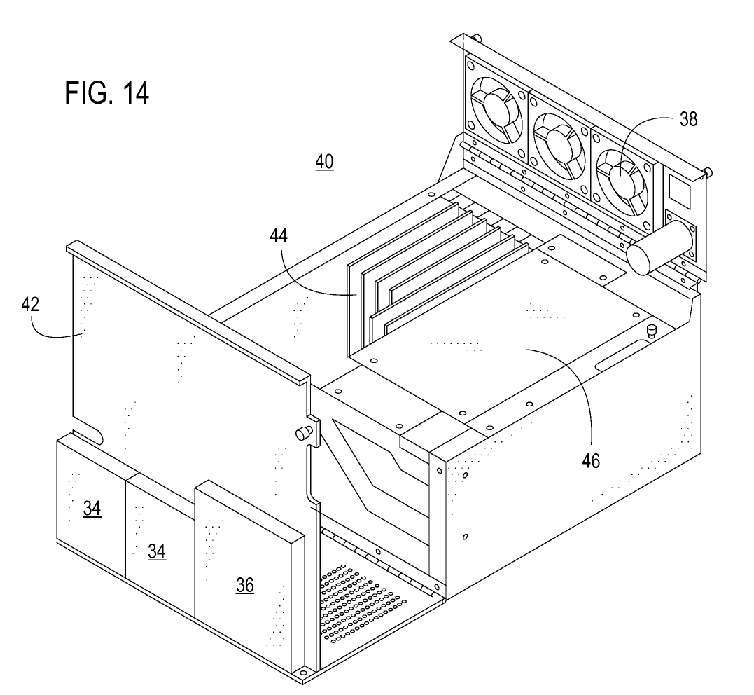

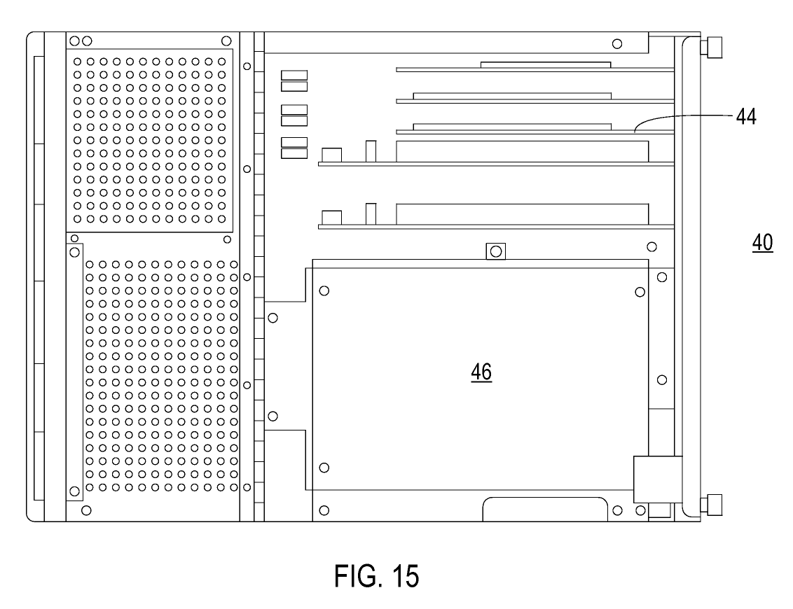

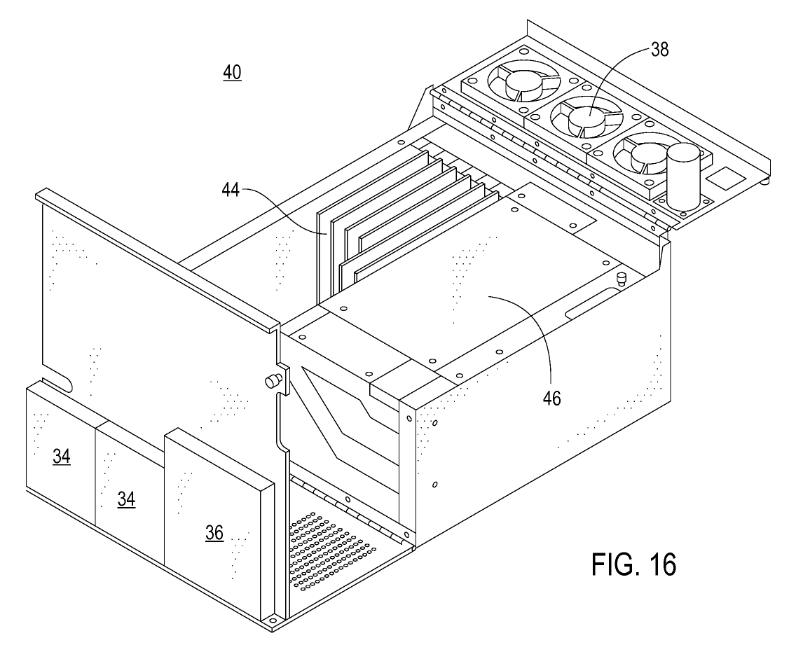

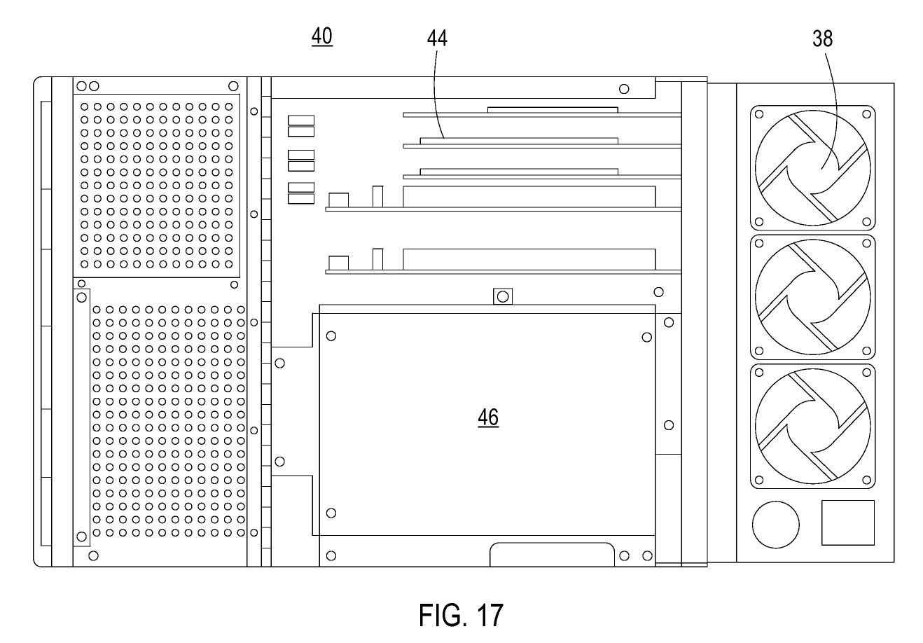

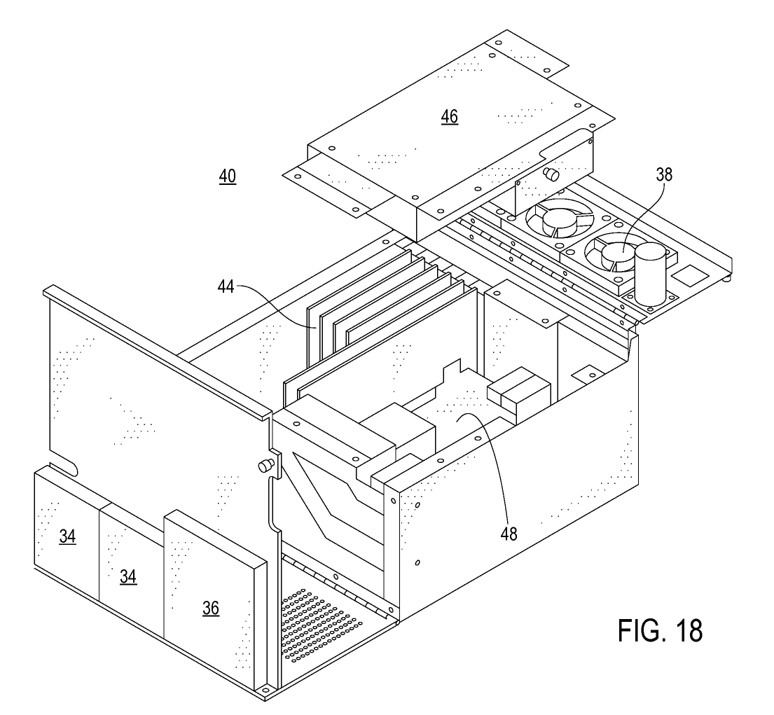

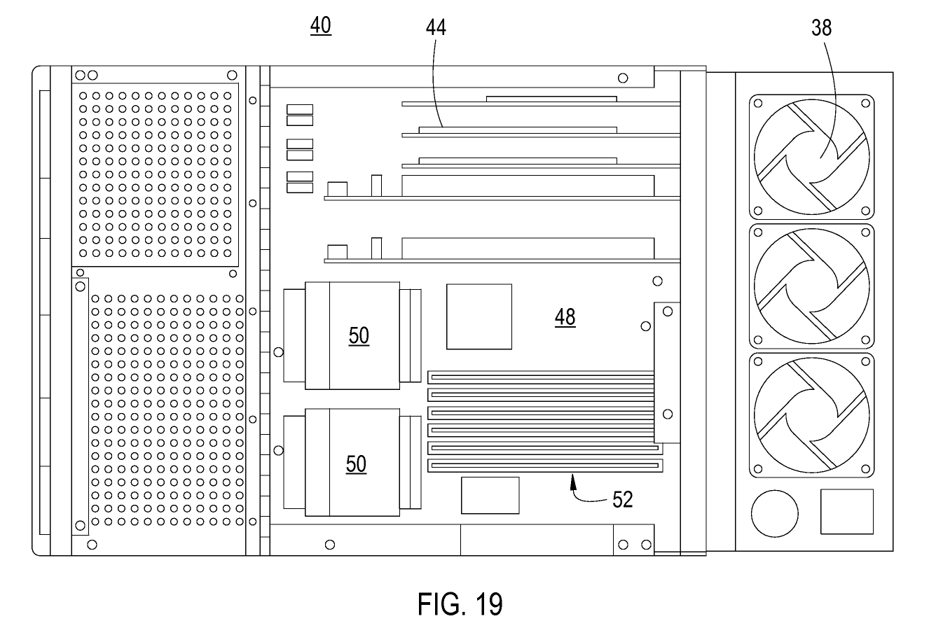

FIGS. 11-13 shows various view of the computer chassis 40 when it is removed from the unit 10. FIG. 14 shows the chassis 40 with an access plate 42 open to allow access to its internal components such as the PCI/PCIe cards 44 and the power supply 46. The power supply 46 is an uninterruptable supply that operates off AC power DC power If a power failure occurs, it allows the unit 10 to run on battery backup for 20 - 30 minutes without interruption of the computer's operation. FIGS. 15-17 show various views of the chassis 40 along with the PCI cards 44, the power supply 46, and the exhaust fans 38. FIGS. 18 and 19 show views of the chassis 40 with the power supply 46 removed. This shows the location of the motherboard 48, the CPUs, and the memory 52 of the computer.

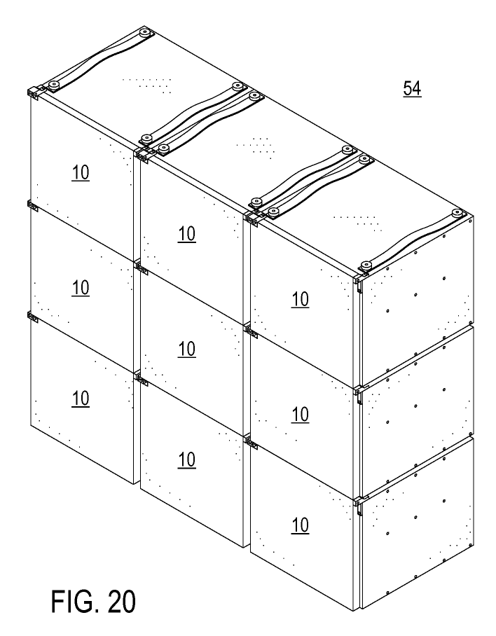

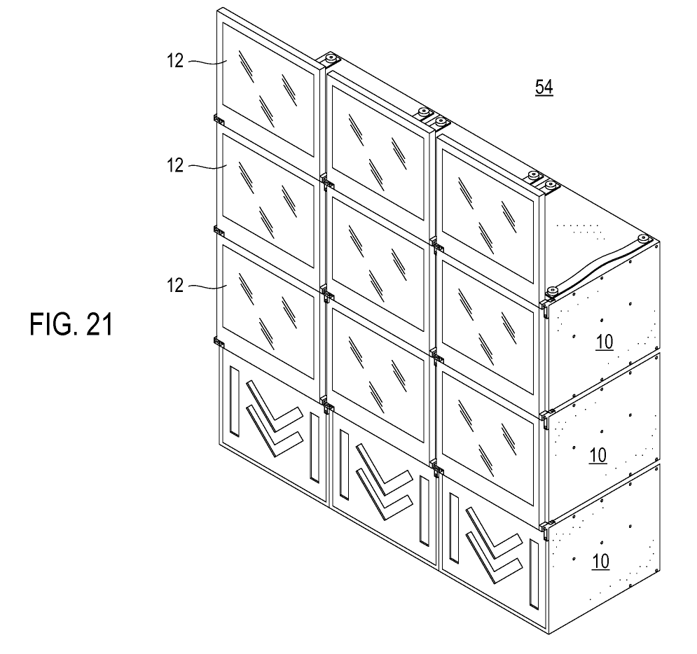

Finally, FIGS. 20 and 21 show multiple units 10 arranged in a 3×3 array 54 in both the open and closed configurations respectively. The array 54 as shown has a height of 34 inches, a width of less than 40 inches, and a depth of less than 30 inches. In both configurations, gaps exist between the units 10 show that the displays do not interfere with the airflow.

It should be clear from the preceding disclosure, that the present invention includes the following advantages: unidirectional cooling airflow across each component; no heat pollution with air flow routed across different components; and maximum efficient of temperature tolerance management.

While the invention has been described with respect to a limited number of embodiments, those skilled in the art, having benefit of this disclosure, will appreciate that other embodiments can be devised which do not depart from the scope of the invention as disclosed here. Accordingly, the scope of the invention should be limited only by the attached claims.

What is claimed is:

1. A space efficient, portable computer unit, comprising:
an aluminum unit case that is generally cubic shaped, where the unit case is about 12.75 inches wide, 11 inches high, and 12.75 inches deep;
a folding flat panel display screen mounted on front of the unit case;
four cushion knobs mounted on the top of the unit case, where the cushion knobs are arranged to provide a seating surface for a second portable computer unit to be stacked on the top of the unit case;
two carry straps mounted on the top of the unit case;
a cooling system comprising,
a series of exhaust fans mounted on the rear of the unit case; and
a filter mounted directly behind an air intake panel on the front of the unit case, where the exhaust fan draws cooling air from the exterior of the unit case through the air intake panel and the filter; and
a plurality of internal computer components mounted inside the unit case, where each internal computer component is arranged to receive cooling air directly from the filter.

2. A space efficient, portable computer unit, comprising:
a unit case that is generally cubic shaped,
a cooling system comprising,
at lease one exhaust fan mounted on the rear of the unit case, and
a filter mounted on the front of the unit case, where the exhaust fan draws cooling air from the exterior of the unit case through the filter; and
a plurality of internal computer components mounted inside the unit case, where each internal computer component is arranged to receive cooling air directly from the filter.

3. The computer unit of claim 1, further comprising:
a folding flat panel display screen mounted on the front of the unit case.

4. The computer unit of claim 1, further comprising:
a plurality of cushion knobs mounted on the top of the unit case, where the cushion knobs are arranged to provide a seating surface for a second portable computer unit to be stacked on the top of the unit case.

5. The computer unit of claim 1, further comprising:
a plurality of carry straps mounted on the top of the unit case.

6. The computer unit of claim 1, where the internal computer components comprise a central processing unit.

7. The computer unit of claim 1, where the internal computer components comprise a removable hard disk drive.

8. The computer unit of claim 1, where the internal computer components comprise a main memory drive.

9. The computer unit of claim 1, where the internal computer components comprise an optical disk drive.

10. The computer unit of claim 1, where the unit case of made of aluminum.

11. The computer unit of claim 1, where the unit case is about 12.75 inches wide, 11 inches high, and 12.75 inches deep.
